(19) United States
(12) Patent Application Publication
(10) Pub. No.: US 2026/0221353 A1
(43) Pub. Date: Jul. 30, 2026

(54) SMALL FORM FACTOR LATCH DETECTOR SWITCH ASSEMBLY FOR PLUGGABLE CIRCUIT PACKS IN SCALABLE NETWORK EQUIPMENT

(71) Applicant: Ciena Corporation, Hanover, MD (US)

(72) Inventors: Chander Prakash Gupta, Gurugram (IN); Sachin Singla, Gurugram (IN); Suyash Agrawal, Gurugram (IN); Sardeep Heda, Rajasthan (IN); Russell Mays, Stockton, CA (US)

(21) Appl. No.: 19/078,371

(22) Filed: Mar. 13, 2025

(30) Foreign Application Priority Data
Jan. 29, 2025 (IN) 202541007298

(51) Int. Cl. H01H 3/46; H05K 1/18

(52) U.S. Cl. CPC H01H 3/46; H05K 1/181; H05K 2201/10053

(57) ABSTRACT

A latch detector switch assembly including a plunger rod having a protruding and terminating ends, a spring cage securing the plunger rod to a printed circuit board of a circuit pack, where the protruding end of the plunger rod protrudes through a port in a faceplate of the circuit pack and be contacted by a latch of the circuit pack when actuated to close/lock the circuit pack in a chassis, thereby translating the plunger rod into the circuit pack and through the spring cage, and a switch coupled to the printed circuit board of the circuit pack and receive the terminating end of the plunger rod when the plunger rod is translated into the circuit pack and through the spring cage, thereby actuating the switch and generating an electric signal indicating that the latch is actuated to close/lock the circuit pack in the chassis.

### CROSS-REFERENCE TO RELATED APPLICATION

The present disclosure claims the benefit of priority of co-pending Indian Patent Application No. 202541007298, filed on Jan. 29, 2025, and entitled “SMALL FORM FACTOR LATCH DETECTOR SWITCH ASSEMBLY FOR PLUGGABLE CIRCUIT PACKS IN SCALABLE NETWORK EQUIPMENT,” the contents of which are incorporated in full by reference.

### TECHNICAL FIELD

The present disclosure relates generally to the telecommunications and networking fields. More particularly, the present disclosure relates to a small form factor latch detector switch assembly for pluggable circuit packs in scalable network equipment.

### BACKGROUND

Scalable network equipment utilizes circuit packs that are equipped with integrated latches/ejectors to securely lock the circuit packs into/eject the circuit packs from a chassis. Failure to lock a circuit pack into a chassis can result in connection problems with the associated backplane connectors. A host controller may check for the proper locking of a circuit pack into a chassis before power on or initialization of the module. Given that there are multiple circuit packs within a system, it becomes crucial to have a mechanism that provides feedback as to whether a particular circuit pack is properly locked in place within a chassis.

Currently, there are two existing solutions available for the above mentioned problem. The first solution involves using a panel mounted push-button switch with a cable assembly. The second solution utilizes a snap acting mechanical switch on the associated printed circuit board (PCBA).

However, both of these existing solutions suffer from various drawbacks. The panel mounted switch solution requires a significant amount of space on the faceplate of the circuit pack, which comes at the expense of optical plug space. This limitation reduces the maximum capability of the system. The snap acting switch solution has a major reliability issue as force is directly transferred to the actuator of the snap acting switch. These actuators on the snap acting switch are force sensitive so they malfunction and/or become damaged if the force applied is not controlled or if the design tolerance allows over-travel of the mechanism. Further, the snap acting switch may also pinch adjacent cables and the like. Moreover, both solutions are not feasible when belly-to-belly optics cages are used as the available space is constrained.

To overcome these limitations and maximize the available faceplate area for optical port placement, as well as to provide sufficient height space for thermal fins on an optical shelf, it is crucial to minimize the size of the latch switch lock mechanism and position it at the bottom side of the PCBA between two cages. This approach ensures maximum utilization of the faceplate space with an improved degree of reliability.

The present background is provided as illustrative environmental context only. It will be readily apparent to those of ordinary skill in the art that the concepts and principles of the present disclosure may be implemented in other environmental contexts equally, without limitation.

### SUMMARY

By addressing the above requirements, the small form factor latch detector switch assembly of the present disclosure not only maximizes the available faceplate area of a circuit pack, but also offers a versatile design that can be used with variety of latches and modules.

The latch detector switch assembly includes a plunger rod that protrudes through a small port in the faceplate of the circuit pack to contact and be translated by the associated latch when the latch is actuated and locked. When the latch is actuated and unlocked, the portion of the plunger rod protruding through the small port in the faceplate of the circuit pack may be separated from the latch. Due to the fact that the portion of the plunger rod protrudes only through the small port in the faceplate of the circuit pack, faceplate area usage is minimized by the latch detector switch assembly and maximized for optical port placement. This setup may be used with a variety of latch types and configurations, such as pivoting latches and the like. The plunger rod is spring biased towards the latch, until the plunger rod is contacted by the latch and translated into the faceplate and circuit pack.

Within the circuit pack, the plunger rod interfaces with a switch that is coupled to the PCBA. For example, a terminating end of the plunger rod may include a cap that protrudes into a photo-interrupter switch when the plunger rod is translated by the closed/locked latch, thereby providing an indication signal that the latch is closed/locked and that the circuit pack is properly secured in the chassis. When the latch is unlocked/opened (and optionally decoupled from the plunger rod), the plunger rod is biased to translate out of the photo-interrupter switch, thereby providing an indication signal that the latch is unlocked/opened and that the circuit pack is not properly secured in the chassis, being ejected, etc. The switch may be any type of non-contact switch, such as a Hall effect switch, or instead may be a contact switch that is physically/mechanically coupled to the terminating end of the plunger rod upon actuation. Of note, the switch is coupled to the PCBA behind the cages for the pluggable optical modules (POMs), where space is available, again maximizing the system space available for optical components.

The plunger rod may be biased out of/away from the switch and through the faceplate of the circuit pack via a spring disposed about the plunger rod near the terminating end of the plunger rod that is captured within a spring cage that is coupled to the PCBA and compressed by a spring guide disposed about the plunger rod. It will be readily apparent to those of ordinary skill in the art that other biasing mechanisms may be used equally.

In some embodiments, the present disclosure provides a latch detector switch assembly including a plunger rod having a protruding end and a terminating end, a spring cage adapted to secure the plunger rod to a printed circuit board of a circuit pack, where the protruding end of the plunger rod is adapted to protrude through a port in a faceplate of the circuit pack and be contacted by a latch of the circuit pack when actuated to close/lock the circuit pack in a chassis, thereby translating the plunger rod into the circuit pack and through the spring cage, and a switch adapted to be coupled to the printed circuit board of the circuit pack and receive the terminating end of the plunger rod when the plunger rod is translated into the circuit pack and through the spring cage, thereby actuating the switch and generating an electric signal indicating that the latch is actuated to close/lock the circuit pack in the chassis. The latch detector switch assembly also includes a spring disposed about the plunger rod within the spring cage and a spring guide coupled to the plunger rod within the spring cage, where the spring guide is adapted to compress the spring within the spring cage when the plunger rod is translated into the circuit pack and through the spring cage, thereby biasing the plunger rod away from the switch and out of the circuit pack through the spring cage when the latch of the circuit pack is actuated to unlock/open the circuit pack in the chassis. The latch of the circuit pack is adapted to be decoupled from the protruding end of the plunger rod when actuated to unlock/open the circuit pack in the chassis when the spring is partially or fully decompressed within the spring cage via translation of the plunger rod and the spring guide within the spring cage. The terminating end of the plunger rod includes a cap that interacts with the switch. A portion of the plunger rod is covered by an insulating heat shrink plastic wrap. In some embodiments, the switch includes a non-contact switch. In some embodiments, the non-contact switch includes a photo-interrupter switch that utilizes a light beam that is broken by introduction of the terminating end of the plunger rod into the photo-interrupter switch.

In some embodiments, the present disclosure provides a circuit pack including a latch adapted to be actuated to be closed/opened to lock the circuit pack in/unlock the circuit pack from a chassis, a faceplate, a printed circuit board, and a latch detector switch assembly including a plunger rod having a protruding end and a terminating end, a spring cage securing the plunger rod to the printed circuit board, where the protruding end of the plunger rod protrudes through a port in the faceplate and is adapted to be contacted by the latch when actuated to close/lock the circuit pack in the chassis, thereby translating the plunger rod into the circuit pack and through the spring cage, and a switch coupled to the printed circuit board and adapted to receive the terminating end of the plunger rod when the plunger rod is translated into the circuit pack and through the spring cage, thereby actuating the switch and generating an electric signal indicating that the latch is actuated to close/lock the circuit pack in the chassis. The circuit pack also includes a spring disposed about the plunger rod within the spring cage and a spring guide coupled to the plunger rod within the spring cage, where the spring guide is adapted to compress the spring within the spring cage when the plunger rod is translated into the circuit pack and through the spring cage, thereby biasing the plunger rod away from the switch and out of the circuit pack through the spring cage when the latch of the circuit pack is actuated to unlock/open the circuit pack in the chassis. The latch of the circuit pack is adapted to be decoupled from the protruding end of the plunger rod when actuated to unlock/open the circuit pack in the chassis when the spring is partially or fully decompressed within the spring cage via translation of the plunger rod and the spring guide within the spring cage. The terminating end of the plunger rod includes a cap that interacts with the switch. A portion of the plunger rod is covered by an insulating heat shrink plastic wrap. In some embodiments, the switch includes a non-contact switch. In some embodiments, the non-contact switch includes a photo-interrupter switch that utilizes a light beam that is broken by introduction of the terminating end of the plunger rod into the photo-interrupter switch. In some embodiments, the latch detector switch assembly is disposed adjacent a plurality of pluggable optical module cages disposed on the printed circuit board. In some embodiments, the plurality of pluggable optical module cages are disposed on top and bottom surfaces of the printed circuit board in a belly-to-belly configuration.

In some embodiments, the present disclosure provides a latch detection method including providing a plunger rod having a protruding end and a terminating end, securing the plunger rod to a printed circuit board of a circuit pack using a spring cage, where the protruding end of the plunger rod is adapted to protrude through a port in a faceplate of the circuit pack and be contacted by a latch of the circuit pack when actuated to close/lock the circuit pack in a chassis, thereby translating the plunger rod into the circuit pack and through the spring cage, and coupling a switch to the printed circuit board of the circuit pack adapted to receive the terminating end of the plunger rod when the plunger rod is translated into the circuit pack and through the spring cage, thereby actuating the switch and generating an electric signal indicating that the latch is actuated to close/lock the circuit pack in the chassis. The latch detection method also includes providing a spring disposed about the plunger rod within the spring cage and a spring guide coupled to the plunger rod within the spring cage, where the spring guide is adapted to compress the spring within the spring cage when the plunger rod is translated into the circuit pack and through the spring cage, thereby biasing the plunger rod away from the switch and out of the circuit pack through the spring cage when the latch of the circuit pack is actuated to unlock/open the circuit pack in the chassis. The latch of the circuit pack is adapted to be decoupled from the protruding end of the plunger rod when actuated to unlock/open the circuit pack in the chassis when the spring is partially or fully decompressed within the spring cage via translation of the plunger rod and the spring guide within the spring cage. In some embodiments, the switch includes a photo-interrupter switch that utilizes a light beam that is broken by introduction of the terminating end of the plunger rod into the photo-interrupter switch.

It will be readily apparent to those of ordinary skill in the art that aspects and features of the various described embodiments may be included, omitted, or combined as desired in a given application, without limitation.

### BRIEF DESCRIPTION OF THE DRAWINGS

The present disclosure is illustrated and described with reference to the various drawings, in which like reference numbers are used to denote like assembly components/method steps, as appropriate, and in which:

FIG. 1 is a planar view of one embodiment of the latch detector switch assembly of the present disclosure assembled in a circuit pack or module and associated chassis or system;

FIG. 2 is a perspective view of one embodiment of the plunger rod of the latch detector switch assembly of the present disclosure;

FIG. 3 is a perspective view of one embodiment of the spring cage of the latch detector switch assembly of the present disclosure;

FIG. 4 is a planar view of one embodiment of the latch detector switch assembly of the present disclosure in an actuated configuration with the latch of the associated circuit pack closed/locked;

FIG. 5 is a planar view of one embodiment of the latch detector switch assembly of the present disclosure in an unactuated configuration with the latch of the associated circuit pack unlocked/open; and

FIG. 6 is a flowchart of one embodiment of the latch detection method of the present disclosure.

It will be readily apparent to those of ordinary skill in the art that aspects and features of the various illustrated embodiments may be included, omitted, or combined as desired in a given application, without limitation.

### DETAILED DESCRIPTION

Again, the small form factor latch detector switch assembly of the present disclosure not only maximizes the available faceplate area of a circuit pack, but also offers a versatile design that can be used with variety of latches and modules.

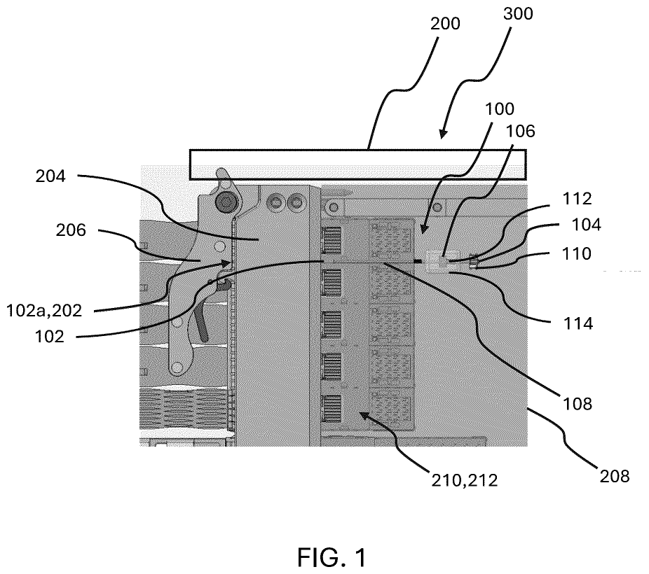

Referring to FIG. 1, the latch detector switch assembly 100 is shown assembled in a circuit pack (or module) 200 and chassis (or system) 300. The latch detector switch assembly 100 includes a plunger rod 102 that protrudes through a small port 202 in the faceplate 204 of the circuit pack 200 to contact and be translated by the associated latch 206 when the latch 206 is actuated and locked, as is illustrated. When the latch 206 is actuated and unlocked, the portion 102a of the plunger rod 102 protruding through the small port 202 in the faceplate 204 of the circuit pack may be separated from the latch 206. Due to the fact that the portion 102a of the plunger rod 102 protrudes only through the small port 202 in the faceplate 204 of the circuit pack 200, faceplate area usage is minimized by the latch detector switch assembly 100 and maximized for optical port placement. The plunger rod 102 is a rigid elongate structure, such as a prismatic metallic rod that is knurled for the securement of components along the length of the plunger rod 102. In the embodiment illustrated, a cap 104 is disposed on the terminating end of the plunger rod 102, and a spring guide 106 is disposed about the plunger rod 102 near the terminating end. Further, because the plunger rod 102 may be metallic and is used in proximity to electrical components, portions of the plunger rod 102 may be coated with insulating plastic tubing or a heat shrink material 108. This setup may be used with a variety of latch types and configurations, such as pivoting latches and the like. As discussed in greater detail below, the plunger rod 102 is spring biased towards the latch 206, until the plunger rod 102 is contacted by the latch 206 and translated into the faceplate 204 and circuit pack 200.

Within the circuit pack 200, the plunger rod 102 interfaces with a switch 110 that is coupled to the PCBA 208. For example, the terminating end of the plunger rod 102 may include the cap 104 that protrudes into a photo-interrupter switch 110 when the plunger rod 102 is translated by the closed/locked latch 206, thereby providing an indication signal that the latch 206 is closed/locked and that the circuit pack 200 is properly secured in the chassis 300. When the latch 206 is unlocked/opened (and optionally decoupled from the plunger rod 102), the plunger rod 102 is biased to translate out of the photo-interrupter switch 110, thereby providing an indication signal that the latch 206 is unlocked/opened and that the circuit pack 200 is not properly secured in the chassis 300, being ejected, etc. The switch 110 may be any type of non-contact switch, such as a Hall effect switch, or instead may be a contact switch that is physically/mechanically coupled to the terminating end of the plunger rod 102 upon actuation. Of note, the switch 110 is coupled to the PCBA 208 behind the cages 210 for the POMs 212, where space is available, again maximizing the system space available for optical components.

The plunger rod 102 may be biased out of/away from the switch 110 and through the faceplate 204 of the circuit pack 200 via a spring 112 disposed about the plunger rod 102 near the terminating end of the plunger rod 102 that is captured within a spring cage 114 that is coupled to the PCBA 208 and compressed by the spring guide 106 disposed about the plunger rod 102. It will be readily apparent to those of ordinary skill in the art that other biasing mechanisms may be used equally.

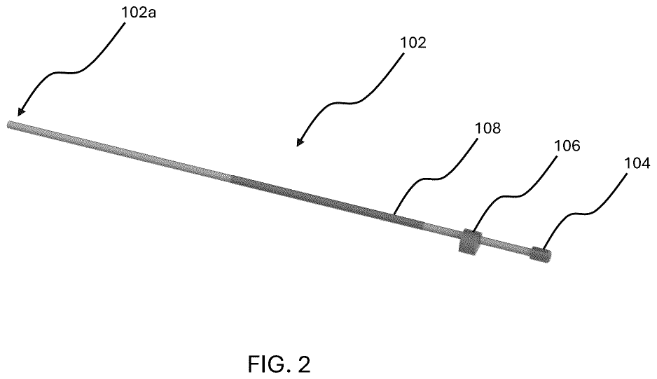

Referring to FIG. 2, again, the plunger rod 102 is a rigid elongate structure, such as a prismatic metallic rod that is knurled for the securement of components along the length of the plunger rod 102. In the embodiment illustrated, the cap 104 is disposed on the terminating end of the plunger rod 102, and the spring guide 106 is disposed about the plunger rod 102 near the terminating end, with both components optionally being insert molded onto the plunger rod 102. The spring 112 may be disposed over the plunger rod 102 between the spring guide 106 and the cap 104 before molding. Further, because the plunger rod 102 may be metallic and is used in proximity to electrical components, portions of the plunger rod 102 may be coated with the insulating plastic tubing or the heat shrink material 108. The protruding end 102a of the plunger rod 102 is ultimately inserted through the small port 202 of the faceplate 204 to allow the protruding end 102a to selectively contact the latch 206, as well as to support the protruding end 102a of the plunger rod 102 at the faceplate 204.

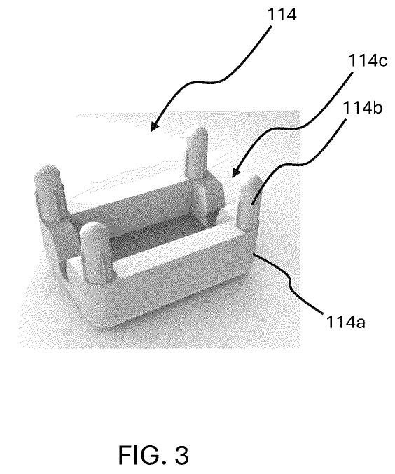

Referring to FIG. 3, the spring cage 114 in which the spring guide 106 and spring 112 coupled to the plunger rod 102 are disposed includes a spring cage housing 114a through which the plunger rod 102 passes and a plurality of spring cage legs 114b that are configured to be press-fit onto or otherwise secured to the PCBA 208. An adhesive may also be used to bond the spring cage housing 114a to the PCBA 208. The spring cage 114 may be manufactured from a molded plastic or other rigid material. The spring cage 114 controls the travel of the plunger rod 102 through a pair of opposed spring cage slots 114c disposed at the ends of the spring cage housing 114a, and the interaction of the spring guide 106, spring 112, and spring cage housing 114a serves to bias the plunger rod 102 away from the switch 110 and towards/through the small port 202 on the faceplate 204 of the circuit pack 200, as is described in greater detail below. The spring cage 114 also guides the terminating end of the plunger rod 102 into the switch 110 when the latch 206 and plunger rod 102 are actuated, while holding the plunger rod 102 captive to the PCBA 208.

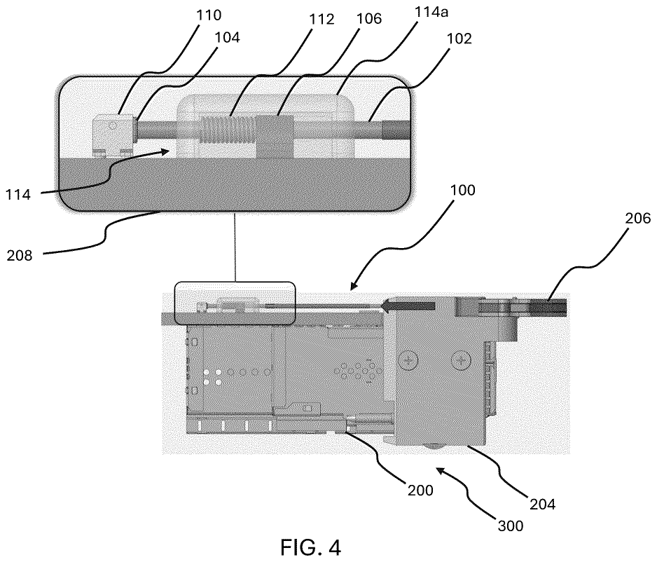

Referring to FIG. 4, when the latch 206 is in a closed/locked configuration, contacting the plunger rod 102, the plunger rod 102 is translated into the circuit pack 200 through the spring cage 114, with the cap 104 of the plunger rod 102 being inserted into the switch 110. This actuates the switch 110 to signal to a controller that the latch 206 is closed/locked. This closed/locked condition of the latch 206 may be displayed to a user and/or used to enable power-up or initialization and operation of the circuit pack 200. In the event that a photo-interrupter switch 110 is used, the cap 104 breaks the light path within the photo-interrupter switch 110 and the photo-interrupter switch 110 generates a corresponding electrical signal. As indicated above, other non-contact switches 110 may be used as well, such as a Hall effect switch or the like. A mechanical switch 110 may also be used, with a mechanical linkage to the plunger rod 102, but such mechanical switches 110 are not necessarily preferred, as they tend to take up more room, require tighter tolerance control, and are more prone to wear and damage. When the latch 206 is closed/locked and the plunger rod 102 is translated towards the switch 110, the spring guide 106 compresses the spring 112 within the spring cage housing 114a, which serves to bias the plunger rod 102 away from the switch 110 when the latch 206 is unlocked/opened.

As illustrated, the latch detector switch assembly 100 takes up minimal space on/adjacent to the PCBA 208 and on the faceplate 204 of the circuit pack 200, thereby maximizing the space available for optical components within the circuit pack 200 and chassis/system 300, especially when belly-to-belly optics cages 210 and POMs 212 are used, for example.

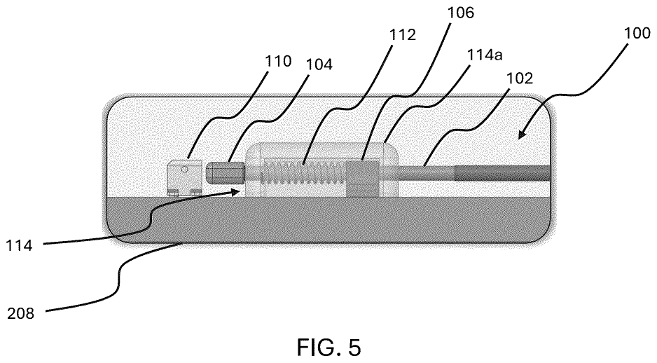

Referring to FIG. 5, when the latch 206 is in a unlocked/opened configuration, disengaging from the plunger rod 102, the plunger rod 102 is biased out of the circuit pack 102 through the spring cage 114, with the cap 104 of the plunger rod 102 being removed from the switch 110. This actuates the switch 110 to signal to a controller that the latch 206 is unlocked/opened. This unlocked/opened condition of the latch 206 may be displayed to a user and/or used to disable power-up or initialization and operation of the circuit pack 200. In the event that a photo-interrupter switch 110 is used, the cap 104 ceases to break the light path within the photo-interrupter switch 110 and the photo-interrupter switch 110 generates a corresponding electrical signal. Again, as indicated above, other non-contact switches 110 may be used as well, such as a Hall effect switch or the like. A mechanical switch 110 may also be used, with a mechanical linkage to the plunger rod 102, but such mechanical switches 110 are not necessarily preferred, as they tend to take up more room, require tighter tolerance control, and are more prone to wear and damage. When the latch 206 is unlocked/opened and the plunger rod 102 is biased away from the switch 110, the spring guide 106 allows the spring 112 to expand within the spring cage housing 114a, which serves to bias the plunger rod 102 away from the switch 110 when the latch 206 is unlocked/opened.

Thus, the present disclosure provides a latch detector switch assembly that is low profile and acts by translation, facilitated by a fastener-free spring-loaded mechanism that transfers linear motion from the latch/ejector movement on the faceplate of the circuit pack through the plunger rod to the photo-interrupter switch on the PCBA within the circuit pack, which detects latch status (opened/closed). The mechanism is held in place captive by the hole in the faceplate and the simple plastic cage, requiring no additional guides. This mechanism does not consume any space on the faceplate, other than the diameter of the plunger rod, and minimal space on the PCBA.

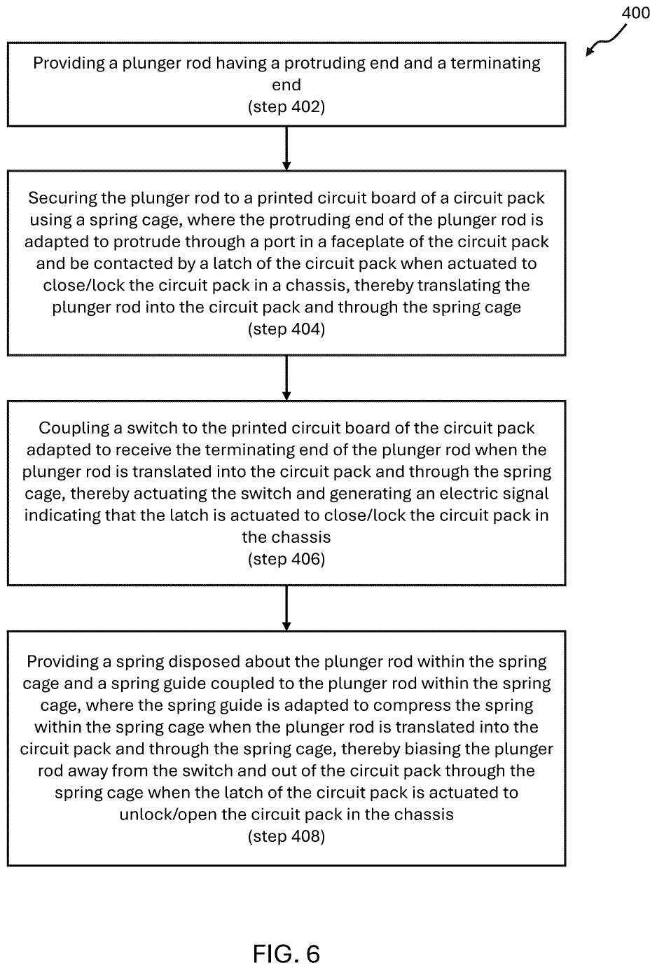

FIG. 6 is a flowchart of one embodiment of the latch detection method 400 of the present disclosure. The latch detection method 400 includes providing a plunger rod having a protruding end and a terminating end (step 402). The latch detection method 400 also includes securing the plunger rod to a printed circuit board of a circuit pack using a spring cage, where the protruding end of the plunger rod is adapted to protrude through a port in a faceplate of the circuit pack and be contacted by a latch of the circuit pack when actuated to close/lock the circuit pack in a chassis, thereby translating the plunger rod into the circuit pack and through the spring cage (step 404). The latch detection method 400 further includes coupling a switch to the printed circuit board of the circuit pack adapted to receive the terminating end of the plunger rod when the plunger rod is translated into the circuit pack and through the spring cage, thereby actuating the switch and generating an electric signal indicating that the latch is actuated to close/lock the circuit pack in the chassis (step 406). The latch detection method 400 still further includes providing a spring disposed about the plunger rod within the spring cage and a spring guide coupled to the plunger rod within the spring cage, where the spring guide is adapted to compress the spring within the spring cage when the plunger rod is translated into the circuit pack and through the spring cage, thereby biasing the plunger rod away from the switch and out of the circuit pack through the spring cage when the latch of the circuit pack is actuated to unlock/open the circuit pack in the chassis (step 408).

Although the present disclosure is illustrated and described with reference to illustrative embodiments and examples, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following non-limiting claims for all purposes.

What is claimed is:

1. A latch detector switch assembly comprising
a plunger rod having a protruding end and a terminating end,
wherein the protruding end of the plunger rod is adapted to protrude through a port in a faceplate of the circuit pack and be contacted by a latch of the circuit pack when actuated to close/lock the circuit pack in a chassis, thereby translating the plunger rod into the circuit pack, and
a switch adapted to be coupled to a printed circuit board of the circuit pack and receive the terminating end of the plunger rod when the plunger rod is translated into the circuit pack, thereby actuating the switch and generating an electric signal indicating that the latch is actuated to close/lock the circuit pack in the chassis.

2. The latch detector switch assembly of claim 1, further comprising a spring cage adapted to secure the plunger rod to the printed circuit board of a circuit pack, wherein a spring is disposed about the plunger rod within the spring cage and a spring guide is coupled to the plunger rod within the spring cage, wherein the spring guide is adapted to compress the spring within the spring cage when the plunger rod is translated into the circuit pack and through the spring cage, thereby biasing the plunger rod away from the switch and out of the circuit pack through the spring cage when the latch of the circuit pack is actuated to unlock/open the circuit pack in the chassis.

3. The latch detector assembly of claim 2, wherein the latch of the circuit pack is adapted to be decoupled from the protruding end of the plunger rod when actuated to unlock/open the circuit pack in the chassis when the spring is partially or fully decompressed within the spring cage via translation of the plunger rod and the spring guide within the spring cage.

4. The latch detector assembly of claim 1, wherein the terminating end of the plunger rod comprises a cap that interacts with the switch.

5. The latch detector assembly of claim 1, wherein a portion of the plunger rod is covered by an insulating heat shrink plastic wrap.

6. The latch detector assembly of claim 1, wherein the switch comprises a non-contact switch.

7. The latch detector assembly of claim 6, wherein the non-contact switch comprises a photo-interrupter switch that utilizes a light beam that is broken by introduction of the terminating end of the plunger rod into the photo-interrupter switch.

8. A circuit pack comprising
a latch adapted to be actuated to be closed/opened to lock the circuit pack in/unlock the circuit pack from a chassis,
a faceplate,
a printed circuit board, and
a latch detector switch assembly comprising
a plunger rod having a protruding end and a terminating end,
wherein the protruding end of the plunger rod protrudes through a port in the faceplate and is adapted to be contacted by the latch when actuated to close/lock the circuit pack in the chassis, thereby translating the plunger rod into the circuit pack, and
a switch coupled to the printed circuit board and adapted to receive the terminating end of the plunger rod when the plunger rod is translated into the circuit pack, thereby actuating the switch and generating an electric signal indicating that the latch is actuated to close/lock the circuit pack in the chassis.

9. The circuit pack of claim 8, wherein the latch detector switch assembly further comprises a spring cage securing the plunger rod to the printed circuit board, wherein a spring is disposed about the plunger rod within the spring cage and a spring guide is coupled to the plunger rod within the spring cage, wherein the spring guide is adapted to compress the spring within the spring cage when the plunger rod is translated into the circuit pack and through the spring cage, thereby biasing the plunger rod away from the switch and out of the circuit pack through the spring cage when the latch of the circuit pack is actuated to unlock/open the circuit pack in the chassis.

10. The circuit pack of claim 9, wherein the latch of the circuit pack is adapted to be decoupled from the protruding end of the plunger rod when actuated to unlock/open the circuit pack in the chassis when the spring is partially or fully decompressed within the spring cage via translation of the plunger rod and the spring guide within the spring cage.

11. The circuit pack of claim 8, wherein the terminating end of the plunger rod comprises a cap that interacts with the switch.

12. The circuit pack of claim 8, wherein a portion of the plunger rod is covered by an insulating heat shrink plastic wrap.

13. The circuit pack of claim 8, wherein the switch comprises a non-contact switch.

14. The circuit pack of claim 8, wherein the non-contact switch comprises a photo-interrupter switch that utilizes a light beam that is broken by introduction of the terminating end of the plunger rod into the photo-interrupter switch.

15. The circuit pack of claim 8, wherein the latch detector switch assembly is disposed adjacent a plurality of pluggable optical module cages disposed on the printed circuit board.

16. The circuit pack of claim 15, wherein the plurality of pluggable optical module cages are disposed on top and bottom surfaces of the printed circuit board in a belly-to-belly configuration.

17. A latch detection method comprising
providing a plunger rod having a protruding end and a terminating end,
wherein the protruding end of the plunger rod is adapted to protrude through a port in a faceplate of the circuit pack and be contacted by a latch of the circuit pack when actuated to close/lock the circuit pack in a chassis, thereby translating the plunger rod into the circuit pack, and
coupling a switch to a printed circuit board of the circuit pack adapted to receive the terminating end of the plunger rod when the plunger rod is translated into the circuit pack, thereby actuating the switch and generating an electric signal indicating that the latch is actuated to close/lock the circuit pack in the chassis.

18. The latch detection method of claim 17, further comprising securing the plunger rod to the printed circuit board of a circuit pack using a spring cage, wherein a spring is disposed about the plunger rod within the spring cage and a spring guide is coupled to the plunger rod within the spring cage, wherein the spring guide is adapted to compress the spring within the spring cage when the plunger rod is translated into the circuit pack and through the spring cage, thereby biasing the plunger rod away from the switch and out of the circuit pack through the spring cage when the latch of the circuit pack is actuated to unlock/open the circuit pack in the chassis.

19. The latch detection method of claim 18, wherein the latch of the circuit pack is adapted to be decoupled from the protruding end of the plunger rod when actuated to unlock/open the circuit pack in the chassis when the spring is partially or fully decompressed within the spring cage via translation of the plunger rod and the spring guide within the spring cage.

20. The latch detection method of claim 17, wherein the switch comprises a photo-interrupter switch that utilizes a light beam that is broken by introduction of the terminating end of the plunger rod into the photo-interrupter switch.
